(19) United States
(12) Patent Application Publication
(10) Pub. No.: US 2026/0176750 A1
(43) Pub. Date: Jun. 25, 2026

(54) METHODS AND SYSTEMS FOR FORMING BORON-CONTAINING LAYERS

(71) Applicant: ASM IP Holding B.V., Almere (NL)

(72) Inventors: João Ricardo Antunes Afonso, Tokyo (JP); Kai Okabe, Kawasaki-shi (JP); Ranjit Rohidas Borude, Leuven (BE); Ming Liu, Helsinki (FI); Mikko Tapani Ruoho, Nurmijärvi (FI); Viljami Pore, Helsinki (FI)

(21) Appl. No.: 19/422,725

(22) Filed: Dec. 17, 2025

Related U.S. Application Data
(60) Provisional application No. 63/736,798, filed on Dec. 20, 2024.

(51) Int. Cl. C23C 16/34; C23C 16/455; H10P 14/60

(52) U.S. Cl. CPC C23C 16/345; C23C 16/45578; H10P 14/6339

(57) ABSTRACT

Methods for forming boron nitride layer on a surface of a substrate by a plasma enhanced atomic layer deposition (PEALD) process are provided. The methods comprise the steps of providing a substrate withing a reaction chamber; and executing at least one deposition cycle. The deposition cycle comprises providing a boron precursor into the reaction chamber, the boron precursor comprising boron halide; and providing a reactive species generated from a plasma produced from a reactant gas into the reaction chamber.

### CROSS-REFERENCE TO RELATED APPLICATIONS

This application claims priority to U.S. Provisional Patent Application Ser. No. 63/736,798 filed Dec. 20, 2024 titled METHODS AND SYSTEMS FOR FORMING BORON-CONTAINING LAYERS, the disclosure of which is hereby incorporated by reference in its entirety.

### FIELD OF INVENTION

The present disclosure generally relates to method and systems for depositing material. More particularly, examples of the disclosure relate to methods and systems for forming boron nitride on a surface of a substrate.

### BACKGROUND OF THE DISCLOSURE

Use of boron nitride (BN) in the formation of electronic devices may be desirable for a number of reasons. For example, boron nitride may be used to form layers with desired dielectric constants, etch or chemical resistance, etch selectivity (e.g., wet or dry etch selectivity relative to silicon oxide and silicon nitride), mechanical properties (e.g., chemical mechanical polishing resistance compared to other dielectric materials), and the like.

Methods for depositing boron nitride films can include plasma-enhanced chemical vapor deposition (PECVD) processes that use borazine as a precursor. Borazine is a relatively expensive precursor. Further, borazine can polymerize during processing, which can lead to undesired contamination and/or film properties. Other techniques have been used to deposit boron nitride, but such techniques can result in films with relatively poor barrier resistance and/or boron nitride films with undesirably high dielectric constants. Accordingly, improved methods for depositing boron nitride are highly desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with examples of the disclosure, exemplary methods of forming boron nitride on a surface of a substrate are provided. The method may comprise the steps of providing a substrate withing a reaction chamber; and executing at least one deposition cycle. The deposition cycle comprises providing a boron precursor into the reaction chamber, the boron precursor comprising boron halide; and providing a reactive species generated from a plasma produced from a reactant gas into the reaction chamber.

In some embodiments, the boron nitride layer consists essentially of boron and nitrogen.

In some embodiments, the boron nitride layer comprises amorphous boron nitride.

In some embodiments, the halide in the boron halide is selected from the list comprising bromine, iodine, chlorine and fluorine. In some embodiments, the boron precursor comprises boron tribromide.

In some embodiments, the reactant gas comprises a mixture of nitrogen gas and hydrogen gas. In some embodiments, the reactant gas comprises ammonia. In some embodiments, the mixture comprises N₂/H₂ ratio between 2:1 and 20:1.

In some embodiments, the plasma is direct plasma.

In some embodiments, the boron nitride layer is deposited over a non-planar substrate with a step coverage of over 85%.

In some embodiments, the boron nitride layer has a dielectric constant of less than 3.5.

In some embodiments, the boron nitride layer has a leakage value of less than 1E-8 A/cm² @ 2 MV/cm.

In some embodiments, the boron nitride layer has a wet etch rate ratio to thermal silicon oxide in dilute hydrofluoric acid (1:100) of less than 0.1.

In some embodiments, the plasma has a power between 100 and 500 W.

In some embodiments, the plasma has a RF-on time between 4 and 12 seconds.

In some embodiments, the deposition process is performed at a temperature of 150-300° C.

In further aspects a device structure is disclosed. The structure comprises a layer of boron nitride formed according to the method according to the current disclosure.

In further aspects a system for forming boron nitride layer on a surface of a substrate is disclosed. The system comprises a reaction chamber for accommodating a substrate; a boron precursor source in fluid communication via a first valve with the reaction chamber; a reactant gas source in fluid communication via a second valve with the reaction chamber; a controller operably connected to the first valve and the second valve and configured and programmed to control: supplying a boron precursor in the reaction chamber; supplying a reactant gas; and depositing the boron nitride on the substrate.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method of forming boron nitride on a surface of a substrate in accordance with at least one example of the disclosure.

FIG. 2 illustrates a device structure comprising a layer of boron nitride in accordance with at least one embodiment of the disclosure.

FIG. 3 illustrates a system for forming boron nitride on a surface of a substrate in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Various embodiments of the present disclosure relate to methods of forming boron nitride on a surface of a substrate, to device structures and devices formed using such methods, and to systems for performing the methods and/or for forming the structures. While the ways in which various embodiments of the present disclosure address drawbacks of prior methods and systems are discussed in more detail below, in general, various embodiments of the disclosure provide improved methods of forming boron nitride that exhibits relatively high etch and/or polishing resistance and/or relatively high thermal stability.

In this disclosure, “gas” can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term “precursor” can refer to a compound that participates in the chemical reaction that produces another compound. The term reactant can be used interchangeably with the term precursor. The term “inert gas” can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas.

As used herein, the term “purge” may refer to a procedure in which an inert or substantially inert gas is provided to a reactor chamber in between two pulses of gases which react with each other. For example, a purge or purging gas may be provided between pulses of two precursors, thus avoiding or at least reducing gas phase interactions between two precursors. It shall be understood that a purge can be effected either in time or in space, or both. For example in the case of temporal purges, a purge step can be used, e.g., in the temporal sequence of providing a first precursor to a reactor chamber, providing a purge gas to the reactor chamber, and providing a second precursor to the reactor chamber, wherein the substrate on which a layer is deposited does not move. In the case of spatial purges, a purge step can be effected by moving a substrate from a first location to which a first precursor is (e.g., continually) supplied, through a purge gas curtain, to a second location to which a second precursor is (e.g., continually) supplied.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments of the disclosure, the substrate may comprise a patterned substrate including high aspect ratio features, such as, for example, trench structures, vertical gap features, horizontal gap features, and/or fin structures. For example, the substrate may comprise one or more substantially vertical gap features and/or one or more substantially horizontal gap features. The term “gap feature” may refer to an opening or cavity disposed between opposing inclined sidewalls or two protrusions extending vertically from the surface of the substrate or opposing inclined sidewalls of an indentation extending vertically into the surface of the substrate. Such a gap feature may be referred to as a “vertical gap feature.” In some embodiments, the vertical gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method according to the disclosure.

The term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. The process may comprise a purge step between introducing precursors.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

As used herein, the term “plasma enhanced atomic layer deposition” (PEALD) may refer to an ALD process in which one or more precursors, reactants, and/or other gases are exposed to a plasma to form excited species.

As used herein, “boron nitride” can be a material that can be represented by a chemical formula that includes boron and nitrogen. In some embodiments, boron nitride may not include significant proportions of elements than boron and nitride. In some embodiments, the boron nitride comprises BN. In some embodiments, the boron nitride may consist essentially of BN. In some embodiments, the boron nitride may consist of boron nitride. A layer consisting of boron nitride may include an acceptable amount of impurities, such as hydrogen, carbon, iodine, bromine and/or the like that may originate from one or more precursors used to deposit boron nitride.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

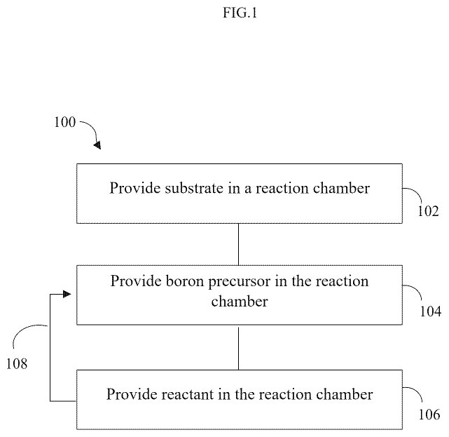

Turning now to the figures, FIG. 1 illustrates a method 100 in accordance with exemplary embodiments of the disclosure. Method 100 can be used to form boron nitride on a surface of a substrate. In the illustrated example, method 100 includes the steps of providing a substrate within a reaction chamber (102), providing a boron precursor to the reaction chamber (104), and providing a reactant to the reaction chamber (106).

During 102, a substrate is provided within a reaction chamber. The reaction chamber used during step 102 can be or include a reaction chamber of a chemical vapor deposition reactor system configured to perform a deposition process. The deposition process may be a chemical vapor deposition process and/or a cyclical deposition process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

In some embodiments, if desired, the exposed surfaces of the substrate may be pretreated to provide reactive sites. In some embodiments, a separate pretreatment step is not required. In some embodiments, the substrate is pretreated to provide a desired surface termination, for example, by exposing the substrate surface to a pretreatment plasma.

In some embodiments of the disclosure, the substrate disposed within the reaction chamber may be heated to a desired deposition temperature for a subsequent deposition. For example, the substrate may be heated to a substrate temperature of less than approximately 600° C., less than approximately 500° C., or less than approximately 450° C., or less than approximately 400° C., or less than approximately 350° C., or less than approximately 300° C., or less than approximately 250° C., or even less than approximately 200° C. In some embodiments of the disclosure, the substrate temperature during step 102 may be greater than room temperature, between approximately 300° C. and approximately 600° C. or approximately 350° C. and approximately 550° C. or approximately 200° C. and approximately 400° C. The lower temperatures may be preferred for plasma-assisted processes, while the higher temperatures may be desired for thermal deposition processes. The temperature during steps 104 and/or 106 can also be within these ranges.

In addition to controlling the temperature of the substrate, the pressure in the reaction chamber may also be regulated to enable deposition of desired boron nitride. In some embodiments, a pressure can be controlled between about 0.5 Torr and about 50 Torr (e.g., for thermal processes) or about 1 Torr and about 10 Torr (e.g., for plasma-enhanced processes). The pressure during steps 104 and/or 106 can also be within these ranges.

Once the temperature of substrate has been set to the desired deposition temperature and pressure in the reaction chamber has been regulated as desired, method 100 may continue to steps 104 and 106. When method 100 includes a CVD process, steps 104 and 106 can overlap. When method 100 includes a cyclical process, steps 104 and 106 can be performed sequentially with an intervening purge step between steps 104 and 106. During step 104, a boron precursor is provided to the reaction chamber. In the case of cyclical deposition, the boron precursor can be pulsed to the reaction chamber. The term “pulse” can be understood to comprise feeding a precursor into the reaction chamber for a predetermined amount of time. Unless otherwise noted, the term “pulse” does not restrict the length or duration of the pulse and a pulse may be any length of time. In some embodiments, in addition to a boron precursor, a gas may be provided to the reaction chamber continuously during a cyclical deposition process. In some embodiments, the gas may comprise both a gas for generation of reactive species utilized during a stage of the PEALD process and may also be utilized as a purge gas to remove excess reactants, reactive species, and reaction byproducts from the reaction chamber.

After an initial surface treatment, if necessary or desired, the boron precursor pulse may be supplied to the substrate. In accordance with some embodiments, the boron precursor may be supplied to the reaction chamber along with a carrier gas flow. In some embodiments, the boron precursor may comprise a volatile boron species that is reactive with the surface(s) of the substrate. The boron precursor pulse may self-saturate the substrate surfaces such that excess constituents of the boron precursor pulse do not further react with the molecular layer formed by this process.

The boron precursor pulse is preferably supplied as a vapor phase reactant. The boron precursor gas may be considered “volatile” for the purposes of the present disclosure if the species exhibits sufficient vapor pressure under the process conditions to transport species to the substrate surface in sufficient concentration to saturate the exposed surfaces.

In some embodiments of the disclosure, the vapor phase boron precursor comprises boron and at least one halogen selected from iodine and bromine. In some cases, the boron precursor does not include fluorine and/or chlorine. In accordance with some embodiments of the disclosure, the boron precursor consists of boron and one or more of iodine and bromine. For example, the boron precursor can be or include boron triiodide (BI₃) and/or boron tribromide (BBr₃).

In some embodiments of the disclosure, the boron precursor may be pulsed into the reaction chamber for a time period from about 0.05 seconds to about 5.0 seconds, or from about 0.1 seconds to about 3 seconds, or even about 0.2 seconds to about 1.0 seconds. In addition, during the contacting of the substrate with the boron precursor, the flow rate of the boron precursor may be less than 20 slm, or less than 10 slm, or less than 7 slm, or less than 5 slm, or even less than 3 slm. In addition, during the contacting of substrate with the boron precursor, the flow rate of the boron precursor may range from about 0.05 to 10 slm, from about 0.1 to 7 slm, or from about 0.1 to about 5 slm. In some embodiments, when the boron precursor is fed into the reaction chamber, nitrogen is used as a carrier gas.

In some embodiments, the excess boron precursor may be purged by stopping the flow of the vapor phase boron precursor while continuing to flow a carrier gas, a purge gas, or a gas mixture, for a sufficient time to diffuse or purge excess reactants and reactant byproducts, if any, from the reaction chamber. In some embodiments, the excess boron precursor may be purged with aid of one or more inert gases, such as nitrogen, helium or argon, that may be flowing throughout the cyclical deposition steps 104 and 106.

In some embodiments, the boron precursor may be purged from the reaction chamber for a time period of about 0.1 seconds to about 10 seconds, or about 0.3 seconds to about 5 seconds, or even about 0.3 seconds to about 1 second. Provision and removal of the boron precursor may be considered as the first or “boron phase” of the exemplary method 100.

Upon completion of the purging the reaction chamber of excess boron precursor and any reaction by-products, the cyclical deposition stage 108 of exemplary PEALD process 100 may continue with a second phase by means of a process block 106 comprising, contacting the substrate with a reactive species generated from a plasma produced from a gas comprising a reactant.

In the second phase, a second reactant comprising a reactive species generated from a plasma is provided to the substrate. In some embodiments, a reactant-based plasma is produced from a gas comprising a reactant. In some embodiments, the reactant may comprise a nitrogen containing gas and an additional gas, such as, nitrogen and hydrogen (N₂/H₂), for example. In some embodiments, the reactant may comprise ammonia. In some embodiments, the nitrogen containing gas (e.g., N>) and the additional gas (e.g., H,) may be introduced into the reaction chamber at a flow rate ratio of nitrogen containing gas to the hydrogen gas is greater than 1:1, or greater than 2:1, or greater than 2:1, or greater than 5:1, or greater than 10:1 or even equal to or greater than 20:1.

For example, a nitrogen-based plasma may be generated by applying RF power from about 10 W to about 2000 W, or from about 50 W to about 1000 W, or from about 100 W to about 500 W. In some embodiments, the plasma may be generated in-situ, while in other embodiments, the plasma may be generated remotely. In some embodiments, a showerhead reactor may be utilized and plasma may be generated between a susceptor (on top of which the substrate is located) and a showerhead plate.

In some embodiments, the reactive species generated from the plasma may contact the substrate for a time period between about 0.1 seconds to about 20 seconds, or about 0.5 seconds to about 10 seconds, or even about 0.5 seconds to about 5 seconds. In some embodiments, the reactive species generated from the plasma may contact the substrate for a time period of between approximately 2 seconds and 10 seconds.

After a time period sufficient to completely saturate and react the previously absorbed molecular layer with the reactant-based plasma pulse, any excess reactant and reaction byproducts may be removed from the reaction chamber. As with the removal of the first reactant, i.e., the vapor phase boron precursor, this step may comprise stopping generation of reactive species and continuing to flow an inert gas, such as a gas comprising nitrogen, helium, and in some embodiments additionally argon. The inert gas flow may flow for a time period sufficient for excess reactive species and volatile reaction byproducts to diffuse out of and be purged from the reaction chamber. For example, the purge process may be utilized for a time period between about 0.1 seconds to about 10 seconds, or about 0.1 seconds to about 4.0 seconds, or even about 0.1 seconds to about 0.5 seconds. Together, the nitrogen-based plasma provision and removal represent a second phase, i.e., a reactive species phase, in the exemplary boron nitride PEALD process 100 of FIG. 1.

The method wherein the substrate is alternately and sequentially contacted with the vapor phase boron precursor and contacted with the reactive species generated from a gas comprising a nitrogen precursor may constitute a unit deposition cycle. In some embodiments of the disclosure, the exemplary PEALD process 100 may comprise repeating the unit deposition cycle one or more times 108. For example, the cyclical deposition stage 108 of exemplary PEALD process 100 may continue whether the desired thickness is not achieved, for example, if the thickness of the boron nitride film is insufficient for the desired device structure, then the PEALD process 100 may return to the process block 104 and the processes of contacting the substrate with the boron precursor and contacting the substrate with the reactant (process block 106) may be repeated one or more times. For example, if the thickness of the boron nitride is less than desired for a particular application, then steps 104 and 106 can be repeated one or more times. In some embodiments, the method comprises from at least 1 cycle to at most 100 cycles, or from at least 2 cycles to at most 80 cycles, or from at least 3 cycles to at most 70 cycles, or from at least 4 cycles to at most 60 cycles, or from at least 5 cycles to at most 50 cycles, or from at least 10 cycles to at most 40 cycles, or from at least 20 cycles to at most 30 cycles. In some embodiments, the method comprises at most 100 cycles, or at most 90 cycles, or at most 80 cycles, or at most 70 cycles, or at most 60 cycles, or at most 50 cycles, or at most 40 cycles, or at most 30 cycles, or at most 20 cycles, or at most 10 cycles, or at most 5 cycles, or at most 4 cycles, or at most 3 cycles, or at most 2 cycles, or a single cycle.

Once the boron nitride film has been deposited to a desired thickness the exemplary PEALD process 100 may end, and the boron nitride film may be subjected to additional processes to form a semiconductor device structure.

While the PEALD cycle is generally referred to herein as beginning with the boron phase, it is contemplated that in other embodiments the cycle may begin with the reactive species phase. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the boron phase. In some embodiments, one or more different PEALD cycles are provided in the deposition process.

In some embodiments, the growth rate of the boron nitride film per unit deposition cycle may be greater than 0.01 nanometers per cycle, or greater than 0.02 nanometers per cycle, or greater than 0.03 nanometer per cycle. In some embodiments, the growth rate of the boron nitride film per unit deposition cycle may be between about 0.01 and about 0.1 nanometer per cycle at a deposition temperature of greater than 250° C.

In some embodiments, the boron nitride may be deposited to a thickness from about 1 nanometer to about 50 nanometers, or from about 5 nanometers to about 30 nanometers, or from about 5 nanometers to about 20 nanometers, or from about 1 nanometer to 10 nanometers. These thicknesses may be achieved in feature sizes (width) below about 100 nanometers, or below about 50 nanometers, or below about 30 nanometers, or below about 20 nanometers, or even below about 10 nanometers.

In some embodiments of the disclosure, the boron nitride may be deposited on a three-dimensional structure, e.g., a non-planar substrate comprising high aspect ratio features. In some embodiments, the step coverage of the boron nitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

As noted above, in accordance with some examples of the disclosure, the deposition process can be a thermal deposition process. In these cases, the deposition process does not include use of a plasma to form activated species for use in the deposition process. For example, the deposition process may not comprise formation or use of plasma, may not comprise formation or use of excited species, and/or may not comprise formation or use of radicals. In the case of thermal cyclical deposition processes, a duration of the step of providing precursor to the reaction chamber can be relatively long to allow the precursor to react with another precursor or a derivative thereof. For example, the duration can be greater than or equal to 5 seconds or greater than or equal to 10 seconds or between about 5 and 10 seconds.

In other cases, as noted herein, a plasma can be used to excite one or more precursors and/or one or more inert gases.

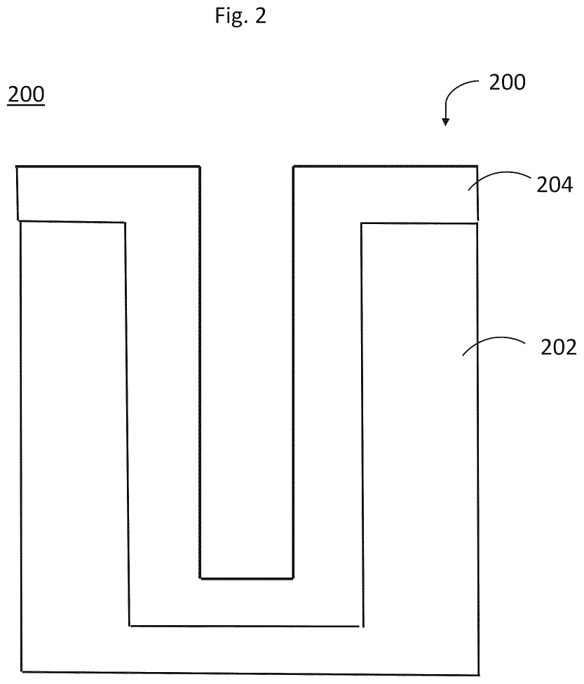

FIG. 2 illustrates a structure/a portion of a device 200 in accordance with additional examples of the disclosure. Device or structure 200 includes a substrate 202 and a layer of boron nitride (or boron nitride layer) 204 formed overlying substrate 202.

Substrate 202 can be or include any of the substrate material described herein. Layer of boron nitride 204 can be formed according to a method described herein. When layer 204 is formed using a cyclical deposition process, a concentration of boron, nitrogen and/or other constituents (e.g., carbon, hydrogen, or the like) in boron nitride layer 204 can vary from a bottom of boron nitride layer 204 to a top of boron nitride layer 204, for example, controlling an amount of boron precursor and/or reactant(s) and/or respective pulse times or number of pulses during one or more deposition cycles. In some cases, boron nitride layer 204 can have a stochiometric composition. Various properties of boron nitride layer 204 can be altered by altering an amount of boron, nitrogen, and/or other compounds in the layer or in a deposition cycle.

In some embodiments, the boron nitride deposited according to a method disclosed herein may have superior etch resistance to comparable boron nitride films deposited by prior processes. For example, the ratio of a wet etch rate of the boron nitride films deposited by a method of the disclosure relative to a wet etch rate of thermal silicon oxide (WERR) in dilute hydrofluoric acid (1:100) may be less than 1.0, or less than 0.5, or less than 0.4, or less than 0.2, or less than 0.1, or between approximately 0.1 and approximately 1.0.

In some embodiments of the disclosure, the boron nitride deposited according to a method disclosed herein may have a wet etch in dilute hydrofluoric acid (1:100) (at room temperature) of less than 1.5 nanometers/minute, or less than 1.0 nanometer/minute, or even less than 0.8 nanometers/minute.

In some embodiments of the disclosure, the boron nitride deposited according to a method disclosed herein may have a leakage value of less than 1E-6 A/cm² @ 2 MV/cm, such as less than 1E-8 A/cm² @ 2 MV/cm at a thickness of 10 nm.

In some embodiments of the disclosure, the boron nitride consists essentially of boron and nitrogen. In some embodiments, the boron nitride film may comprise a carbon doped boron nitride.

In some cases, the layer of boron nitride 204 is amorphous. In some cases, the layer of boron nitride 204 is not polycrystalline.

A dielectric constant of the layer of boron nitride 204 can be less than 4, less than 3.7, or less than 3.5. The dielectric constant can be greater than 2 or greater than 2.5 or greater than 2.7.

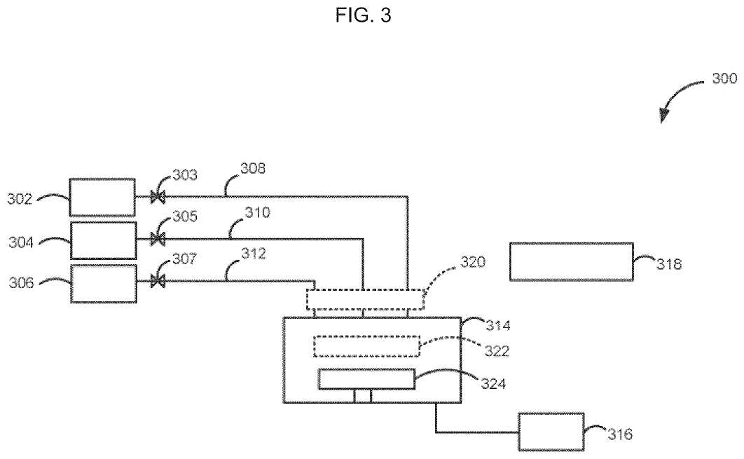

FIG. 3 illustrates a system 300 in accordance with yet additional exemplary embodiments of the disclosure. System 300 can be used to perform a method as described herein and/or form a structure or device portion as described herein.

In the illustrated example, system 300 includes one or more reaction chambers 314, a boron precursor source 302 in fluid communication via a first valve 303 with reaction chamber 314, a nitrogen source 304 in fluid communication via a second valve 305 with reaction chamber 314, a third gas source (e.g., a carrier and/or purge gas source) 306 in fluid communication via a third valve 307 with reaction chamber 314; an exhaust source 316, and a controller 318. System 300 can optionally include a remote plasma source 320 to excite a gas from one or more sources 302-306.

Reaction chamber 314 can include any suitable reaction chamber, such as an ALD or CVD reaction chamber. Reaction chamber 314 can include a gas distribution system 322, such as a showerhead, and a susceptor 324 to retain a substrate. Gas distribution system 322 and susceptor 324 can be used to form a direct plasma within reaction chamber 314.

Boron precursor source 302 can include a vessel and one or more boron precursors as described herein—alone or mixed with one or more carrier (e.g., inert) gases. Nitrogen source 304 can include a vessel and one or more precursors (e.g., nitrogen precursor) as described herein—alone or mixed with one or more carrier gases. Third gas source 306 can include one or more inert and/or carrier gases as described herein. Although illustrated with three gas sources 302-306, system 300 can include any suitable number of gas sources. Gas sources 302-306 can be coupled to reaction chamber 314 via lines 308-312, which can each include flow controllers, valves, heaters, and the like.

Exhaust source 316 can include one or more vacuum pumps.

Controller 318 can include electronic circuitry and software to selectively operate valves, manifolds, heaters, pumps and other components included in system 300. Such circuitry and components can operate to introduce precursors, reactants, and purge gases from the respective sources 302-306. Controller 318 can control timing of gas pulse sequences, temperature of the substrate and/or reaction chamber, pressure within the reaction chamber, and various other operations to provide proper operation of system 300. Controller 318 can include control software to electrically or pneumatically control valves to control flow of precursors, reactants and purge gases into and out of the reaction chamber 314. Controller 318 can include modules, such as a software or hardware component, e.g., a FPGA or ASIC, which perform certain tasks. A module can advantageously be configured to reside on the addressable storage medium of the control system and be configured to execute one or more processes. By way of example, controller 318 can be operably connected to first valve 303 and second valve 305 and configured and programmed to control: supplying a boron precursor comprising one or more of iodine and bromine in the reaction chamber and supplying a nitrogen precursor comprising a substituted hydrazine compound to the reaction chamber to thereby deposit boron nitride on the substrate.

Other configurations of system 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 314. Further, as a schematic representation of an apparatus, many components have been omitted for simplicity of illustration, and such components may include, for example, various valves, manifolds, purifiers, heaters, containers, vents, and/or bypasses.

During operation of deposition system 300, substrates, such as semiconductor wafers (not illustrated), are transferred from, e.g., a substrate handling system to reaction chamber 314. Once substrate(s) are transferred to reaction chamber 314, one or more gases from gas sources 302-306, such as precursors, reactants, carrier gases, and/or purge gases, are introduced into reaction chamber 314 to deposit boron nitride.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of forming boron nitride layer on a surface of a substrate, the method comprising the steps of:
providing a substrate withing a reaction chamber; and
executing at least one deposition cycle, wherein the deposition cycle comprises
providing a boron precursor into the reaction chamber, the boron precursor comprising boron halide; and
providing a reactive species generated from a plasma produced from a reactant gas into the reaction chamber.

2. The method according to claim 1, wherein the boron nitride layer consists essentially of boron and nitrogen.

3. The method according to claim 1, wherein the boron nitride layer comprises amorphous boron nitride.

4. The method according to claim 1, wherein the halide in the boron halide is selected from the list comprising bromine, iodine, chlorine and fluorine.

5. The method according to claim 1, wherein the boron precursor comprises boron tribromide.

6. The method according to claim 1, wherein the reactant gas comprises a mixture of nitrogen gas and hydrogen gas.

7. The method according to claim 5, wherein the mixture comprises N₂/H₂ flow rate ratio between 2:1 and 20:1.

8. The method according to claim 1, wherein the plasma is direct plasma.

9. The method according to claim 1, wherein the boron nitride layer is deposited over a non-planar substrate with a step coverage of over 85%.

10. The method according to claim 1, wherein the boron nitride layer has a dielectric constant of less than 3.5.

11. The method according to claim 1, wherein the boron nitride layer has a leakage value of less than 1E-8 A/cm² @ 2 MV/cm.

12. The method according to claim 1, wherein the boon nitride layer has a wet etch rate ratio to thermal silicon oxide in dilute hydrofluoric acid (1:100) of less than 0.1.

13. The method according to claim 1, wherein the plasma is generated by applying RF power between 100 and 500 W.

14. The method according to claim 1, wherein the plasma may contact the substrate for a time period between 4 and 12 seconds.

15. The method according to claim 1, wherein the deposition process is performed at a temperature of 150-300° C.

16. A device structure comprising a layer of boron nitride formed according to the method of claim 1.

17. A system for forming boron nitride layer on a surface of a substrate, the system comprising:
a reaction chamber for accommodating a substrate;
a boron precursor source in fluid communication via a first valve with the reaction chamber;
a reactant gas source in fluid communication via a second valve with the reaction chamber;
a controller operably connected to the first valve and the second valve and configured and programmed to control:
supplying a boron precursor in the reaction chamber;
supplying a reactant gas; and
depositing the boron nitride on the substrate.
